(19) United States
(12) Patent Application Publication
(10) Pub. No.: US 2024/0355706 A1
(43) Pub. Date: Oct. 24, 2024

(54) SEMICONDUCTOR DEVICE AND METHOD FOR FORMING THE SAME

(71) Applicant: Taiwan Semiconductor Manufacturing Company, Ltd., Hsinchu (TW)

(72) Inventor: Ching-Wei TSAI, Hsinchu City (TW)

(21) Appl. No.: 18/302,987

(22) Filed: Apr. 19, 2023

(51) Int. Cl. H01L 23/48; H01L 21/768; H01L 23/00; H01L 23/498; H01L 23/522; H01L 25/065

(52) U.S. Cl. CPC H01L 23/481; H01L 21/76898; H01L 23/49827; H01L 23/5226; H01L 24/16; H01L 25/0657; H01L 2224/16227; H01L 2225/06541

(57) ABSTRACT

A method for forming a semiconductor device is provided. The method includes forming a first device layer on a first substrate, forming a dielectric structure on the first device layer, forming a second device layer on the dielectric structure, wherein the first device layer and the second device layer are disposed on opposite sides of the dielectric structure. After the second device layer is formed on the dielectric structure, the method further includes forming a first interconnect structure on the second device layer, removing the first substrate to expose the first device layer, forming vias through the dielectric structure. After the vias are formed, the method further includes forming a second interconnect structure on the first device layer. The vias are electrically connected to both the first interconnect structure and the second interconnect structure.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to 1I are schematic views of a process for forming a semiconductor device, in accordance with some embodiments.

FIGS. 2A and 2B show processes for forming a semiconductor device with an interposer disposed on the second interconnect structure, in accordance with some embodiments.

FIG. 3 is a schematic view of a semiconductor device, in accordance with some embodiments of the present disclosure.

FIG. 4 is a schematic view of a semiconductor device, in accordance with some embodiments of the present disclosure.

FIG. 5 is a schematic view of a semiconductor device, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Unless defined otherwise, all technical and scientific terms used herein have the same meaning as commonly understood by one of ordinary skill in the art to which this invention belongs. It should be appreciated that each term, which is defined in a commonly used dictionary, should be interpreted as having a meaning conforming to the relative skills and the background or the context of the present disclosure, and should not be interpreted in an idealized or overly formal manner unless defined otherwise.

The term “about” as used herein indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

Use of ordinal terms such as “first”, “second”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

Furthermore, the phrase “in a range between a first value and a second value” or “in a range from a first value to a second value” indicates that the range includes the first value, the second value, and other values between them.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. Where applicable, the term “substantially” may also relate to 90% or higher, such as 95% or higher, especially 99% or higher, including 100%. Furthermore, terms such as “substantially parallel” or “substantially perpendicular” are to be interpreted as not to exclude insignificant deviation from the specified arrangement and may include for example deviations of up to 10°. The word “substantially” does not exclude “completely” e.g. a composition which is “substantially free” from Y may be completely free from Y.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

A back-to-back monolithic 3D stacking process is proposed in some embodiments of the present disclosure, which includes a feed-through-Via-like (FTV) design and multiple bonding/de-bonding processes. The FTV design enables high signal connectivity and power delivery network (PDN) and signal from a package substrate to bottom/top device layers. The multiple bonding/de-bonding processes enable stacking of ICs with minimized low temperature process constraint, such as avoiding middle-end-of-line (MEOL)/back-end-of-line (BEOL) from high-temperature risks.

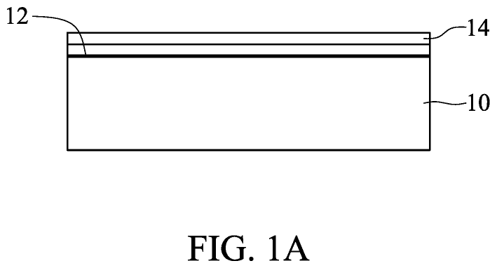

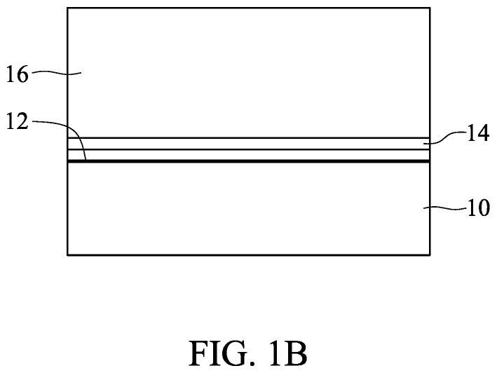

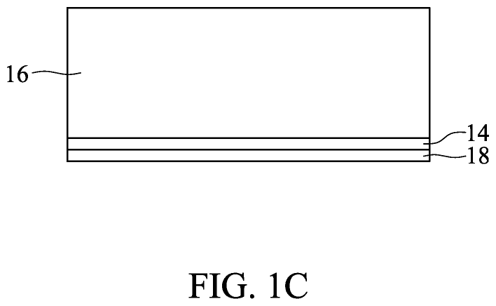

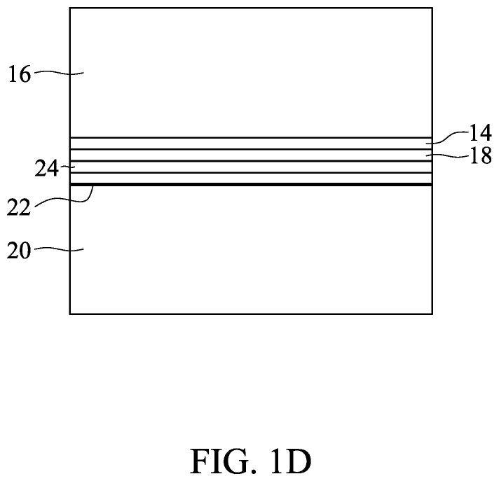

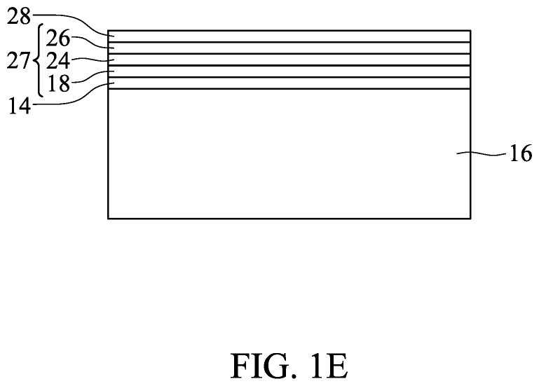

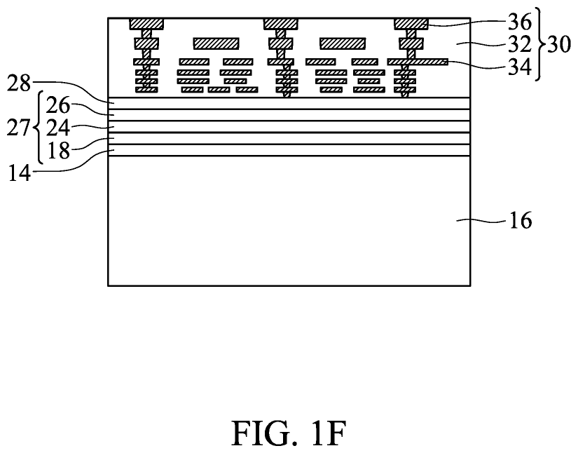

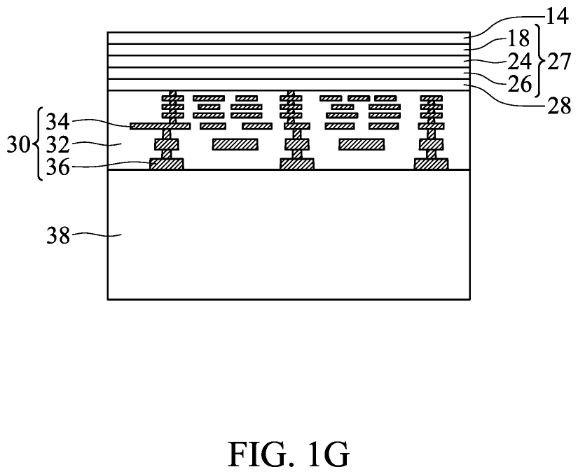

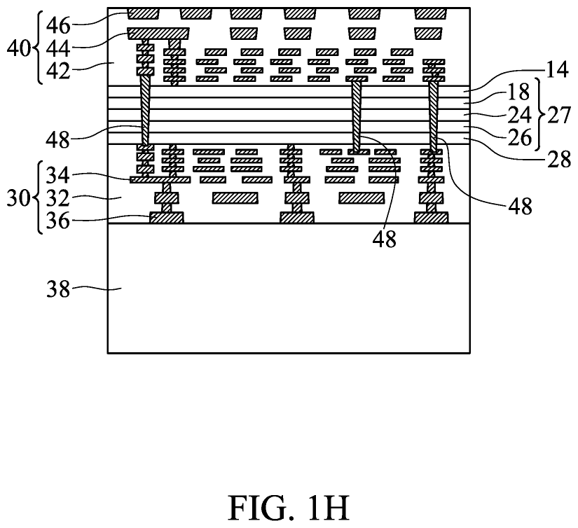

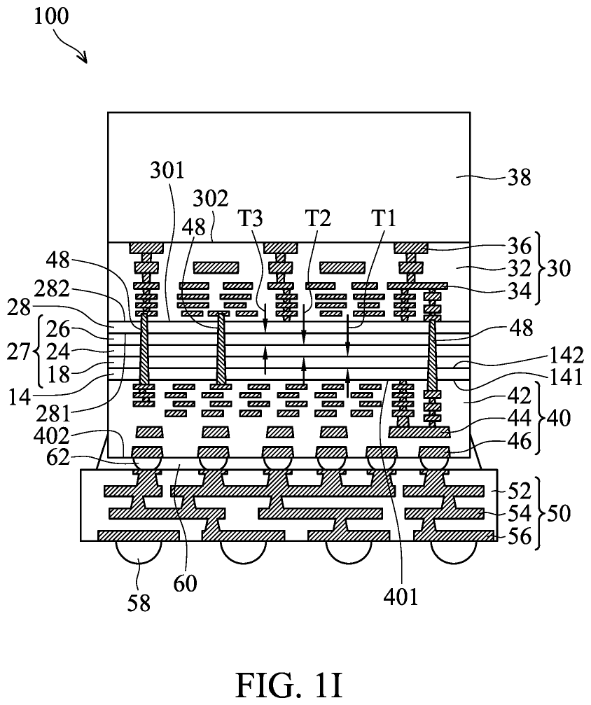

FIG. 1A to 1I are schematic views of a process for forming a semiconductor device 100, in accordance with some embodiments. As shown in FIG. 1A, a first wafer 10 is provided with a first etch stop layer 12 in the first wafer 10, and a first device layer 14 is disposed on the first wafer 10.

In some embodiments, the first wafer 10 may be a semiconductor wafer such as a silicon wafer. Alternatively or additionally, the first wafer 10 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP. In some embodiments, the first etch stop layer 12 may be formed by an epitaxial process. In some embodiments, the material of the first etch stop layer 12 may include SiGe_{10%}˜SiGe_{30%}.

In some embodiments, the first device layer 14 are formed on the first wafer 10 during the front-end-of-line (FEOL) processes. In some embodiments, the first device layer 14. Various microelectronic components may be formed in or on the first device layer 14. In some embodiments, the various microelectronic components may include transistor components such as source/drain features, gate structures, gate spacers, source/drain contacts, gate contacts, isolation structures including shallow trench isolation (STI), or any other suitable components. Transistor components formed on the first device layer 14 may include multi-gate devices, such as fin-type field effect transistors (FinFETs), multi-bridge-channel (MBC) transistors, or other FETs with nanostructures. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. Depending on the shape of the channel member that may resemble a wire or a sheet, an MBC transistor may also be referred to as nanowire transistors or nanosheet transistors.

As shown in FIG. 1B, a first substrate 16 is disposed on the first device layer 14. In some embodiments, the first substrate 16 may be a semiconductor wafer such as a silicon wafer. Alternatively or additionally, the first substrate 16 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

As shown in FIG. 1C, a thinning process is performed to remove a portion of the first wafer 10 until the first etch stop layer 12 is removed, and the remained first wafer 10 refers to a first material layer 18. In some embodiments, the thinning process may include a planarization process (e.g., a mechanical grinding, a CMP, or the like), an etch-back process, a combination thereof, or the like.

As shown in FIG. 1D, a second wafer 20 having a second etch stop layer 22 is bonded to the first material layer 18 through a dielectric bonding layer 24. In some embodiments, the second wafer 20 may be a semiconductor wafer such as a silicon wafer. Alternatively or additionally, the second wafer 20 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GalnP, and/or GaInAsP. In some embodiments, the second etch stop layer 22 may be formed by an epitaxial process. In some embodiments, the material of the second etch stop layer 22 may include SiGe_{10%}˜SiGe_{30%}. In some embodiments, the dielectric bonding layer 24 includes silicon oxide (SiOₓ).

As shown in FIG. 1E, the entire structure is flipped over, and then a thinning process is performed to remove a portion of the second wafer 20 until the second etch stop layer 22 is removed, and the remained second wafer 20 refers to a second material layer 26. In some embodiments, the thinning process may include a planarization process (e.g., a mechanical grinding, a CMP, or the like), an etch-back process, a combination thereof, or the like. In some embodiments, the first material layer 18, the dielectric bonding layer 24, and the second material layer 26 may be referred to a dielectric structure 27.

Afterwards, a second device layer 28 is disposed on the second material layer 26. In some embodiments, the second device layer 28 are formed on the second material layer 26 during the Mid-End-of-Line (MEOL) processes. Various microelectronic components may be formed in or on the second device layer 28. In some embodiments, the various microelectronic components may include transistor components such as source/drain features, gate structures, gate spacers, source/drain contacts, gate contacts, isolation structures including shallow trench isolation (STI), or any other suitable components. Transistor components formed on the second device layer 28 may include multi-gate devices, such as fin-type field effect transistors (FinFETs), multi-bridge-channel (MBC) transistors, or other FETs with nanostructures. A FinFET has an elevated channel wrapped by a gate on more than one side (for example, the gate wraps a top and sidewalls of a “fin” of semiconductor material extending from a substrate). An MBC transistor has a gate structure that can extend, partially or fully, around a channel region to provide access to the channel region on two or more sides. Because its gate structure surrounds the channel regions, an MBC transistor may also be referred to as a surrounding gate transistor (SGT) or a gate-all-around (GAA) transistor. Depending on the shape of the channel member that may resemble a wire or a sheet, an MBC transistor may also be referred to as nanowire transistors or nanosheet transistors.

As shown in FIG. 1F, a first interconnect structure 30 is formed on and in contact with the second device layer 28. In some embodiments, the first interconnect structure 30 includes a dielectric material layer 32, a plurality of conductive features 34 disposed in the dielectric material layer 32, and conductive pads 36 exposed from the dielectric material layer 32.

In accordance with some embodiments of the present disclosure, the dielectric material layer 32 is formed of or includes an organic material, which may be a polymer. The organic material may also be a photo-sensitive material. For example, the dielectric material layer 32 may be formed of or comprises polyimide, polybenzoxazole (PBO), benzocyclobutene (BCB), or the like.

In accordance with some embodiments, the formation of the conductive features 34 and the conductive pads 36 may include forming a metal seed layer (not shown), which includes some portions over the dielectric material layer 32, and some other portions extending into the dielectric material layer 32. A patterned mask (not shown) such as a photoresist is then formed over the metal seed layer, followed by a metal plating process to deposit a metallic material on the exposed metal seed layer. The patterned mask and the portions of the metal seed layer covered by the patterned mask are then removed, the leaving conductive features 34 and the conductive pads 36. The plated material may include copper, aluminum, cobalt, nickel, gold, silver, tungsten, or alloys thereof. In accordance with some embodiments of the present disclosure, the metal seed layer includes a titanium layer and a copper layer over the titanium layer. The metal seed layer may be formed using, for example, physical vapor deposition (PVD) or a like process. The plating may be performed using, for example, an electrochemical plating process.

In some embodiments, as shown in FIG. 1G, the entire structure is flipped over, a second substrate 38 is provided on and in contact with the first interconnect structure 30, and then the first substrate 16 is removed.

In some embodiments, the second substrate 38 may be a semiconductor wafer such as a silicon wafer. Alternatively or additionally, the second substrate 38 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GalnP, and/or GaInAsP.

In some embodiments, As shown in FIG. 1H, vias 48 are formed to penetrate the dielectric structure 27 (including the first material layer 18, the dielectric bonding layer 24, and the second material layer 26). In accordance with some embodiments, the formation of the vias 48 may include forming an opening in the first material layer 18, the dielectric bonding layer 24, the second material layer 26, a portion of the first interconnect structure 30, and a portion of the second interconnect structure 40. Afterwards, a metal seed layer (not shown) is formed in the opening. A patterned mask (not shown) such as a photoresist is then formed over the metal seed layer, followed by a metal plating process to deposit a metallic material on the exposed metal seed layer. The patterned mask and the portions of the metal seed layer covered by the patterned mask are then removed, the leaving the vias 48. The plated material may include copper, aluminum, cobalt, nickel, gold, silver, tungsten, or alloys thereof. In accordance with some embodiments of the present disclosure, the metal seed layer includes a titanium layer and a copper layer over the titanium layer. The metal seed layer may be formed using, for example, physical vapor deposition (PVD) or a like process. The plating may be performed using, for example, an electrochemical plating process. In some embodiments, the material of the vias 48 may be different from the material of the conductive features 43 and the conductive features 44.

In some embodiments, a barrier layer (not shown) may be provided between the vias 48 and the first material layer 18, the dielectric bonding layer 24, and the second material layer 26 to prevent diffusion from occurring. In some embodiments, the barrier layer may include titanium, titanium nitride, tantalum, tantalum nitride, or the like.

As shown in FIG. 1H, a second interconnect structure 40 is formed on and in contact with the first device layer 14. In some embodiments, the second interconnect structure 40 includes a dielectric material layer 42, a plurality of conductive features 44 disposed in the dielectric material layer 42, and conductive pads 46 exposed from the dielectric material layer 42.

In accordance with some embodiments of the present disclosure, the dielectric material layer 42 is formed of or includes an organic material, which may be a polymer. The organic material may also be a photo-sensitive material. For example, the dielectric material layer 42 may be formed of or comprises polyimide, polybenzoxazole (PBO), benzocyclobutene (BCB), or the like.

In accordance with some embodiments, the formation of the conductive features 44 and the conductive pads 46 may include forming a metal seed layer (not shown), which includes some portions over the dielectric material layer 42, and some other portions extending into the dielectric material layer 42. A patterned mask (not shown) such as a photoresist is then formed over the metal seed layer, followed by a metal plating process to deposit a metallic material on the exposed metal seed layer. The patterned mask and the portions of the metal seed layer covered by the patterned mask are then removed, the leaving conductive features 44 and the conductive pads 46. The plated material may include copper, aluminum, cobalt, nickel, gold, silver, tungsten, or alloys thereof. In accordance with some embodiments of the present disclosure, the metal seed layer includes a titanium layer and a copper layer over the titanium layer. The metal seed layer may be formed using, for example, physical vapor deposition (PVD) or a like process. The plating may be performed using, for example, an electrochemical plating process.

In some embodiments, the vias 48 are electrically connected to the conductive features 44 of the second interconnect structure 40. In some embodiments, the vias 48 extend into the dielectric material layer 32 to contact the conductive features 34, and extend into the dielectric material layer 42 to contact the conductive features 44. In some embodiments, each of the vias 48 have a resistance between about 10Ω (Ohm) and about 20052. In some embodiments, the vias have a pitch between about 0.1 μm and about 1 μm. In some embodiments, the height of the vias 48 may be between about 300 nm and about 1000 nm.

In some embodiments, the vias 48 are Feed-through-Vias (FTV), which enables high signal connectivity between the electrical components in the first device layer 14 and the second device layer 28. In some embodiments, the vias 48 may be used for both power delivery network (PDN) connections and signal connections to the first device layer 14 and the second device layer 28, providing a means for efficient power and signal distribution throughout the semiconductor device 100. These connections allow for effective communication between different components within the first device layer 14 and the second device layer 28, enabling them to operate more effectively and reliably. With the inclusion of the vias 48, the semiconductor device 100 is better equipped to handle the complex demands of modern electronic applications.

In some embodiments, as shown in FIG. 1I, an interposer 50 is disposed below the second interconnect structure 40 through electrical connectors 62. In some embodiments, the width of the vias 48 gradually increases from the second substrate 38 to the interposer 50.

In some embodiments, the interposer 50 includes a board 52 and conductive elements 54 and conductive pads 56 disposed in the board 52. In some embodiments, the board 52 may be made of or include a polymer material, a ceramic material, a metal material, a semiconductor material, one or more other suitable materials, or a combination thereof. For example, the board 52 includes resin, prepreg, glass, and/or ceramic. In cases where the board 52 is made of a metal material or a semiconductor material, dielectric layers may be formed between the board 52 and the conductive elements 54 and conductive pads 56 to prevent short circuiting. The conductive elements 54 and the conductive pads 56 may include conductive wires and vias, and may be made of or include copper, aluminum, cobalt, nickel, gold, silver, tungsten, one or more other suitable materials, or a combination thereof.

In some embodiments, electrical connectors 58 may be disposed on the interposer 50 and in contact with the conductive pads 56 to perform electrical connection. In some embodiments, the electrical connectors 62 may include conductive pillars, solder balls, controlled collapse chip connection (C4) bumps, micro bumps, one or more other suitable bonding structures, or a combination thereof.

In some embodiments, an underfill layer 60 is provided between the second interconnect structure 40 and the interposer 50 and surrounding the electrical connectors 62 to protect the electrical connectors 62. In some embodiments, the underfill layer 60 may include an epoxy, a resin, a filler material, a stress release agent (SRA), an adhesion promoter, another suitable material, or a combination thereof. In some embodiments, the fillers may include insulating fibers, insulating particles, other suitable elements, or a combination thereof. In some embodiments, an underfill material in liquid state is dispensed into a gap between second interconnect structure 40 and the interposer 50 to reinforce the strength of the electrical connectors 62 and therefore the overall package structure. After the dispensing, the underfill material is cured to form the underfill layer 60. In some other embodiments, the underfill layer 60 is not formed.

In some embodiments, the electrical connectors 62 may include conductive pillars, solder balls, controlled collapse chip connection (C4) bumps, micro bumps, one or more other suitable bonding structures, or a combination thereof. Therefore, the formation of the semiconductor device 100 is completed.

In some embodiments, the first interconnect structure 30 is separated from the second material layer 26 by the second device layer 28, and the second interconnect structure 40 is separated from the first material layer 18 by the first device layer 14.

In some embodiments, the first interconnect structure 30 has a first side 301 and second side 302 opposite from each other. The first device layer 14 has a first side 141 and a second side 142 opposite from each other. The second device layer 28 has a first side 281 and a second side 282 opposite from each other. The second interconnect structure 40 has a first side 401 and second side 402 opposite from each other. In some embodiments, the first side 301 of the first interconnect structure 30 faces the second side 142 of the first device layer 14 and the second side 282 of the second device layer 28, and the first side 401 of the second interconnect structure 40 faces the first side 141 of the first device layer 14 and the first side 281 of the second device layer 28.

The first interconnect structure 30 and the second interconnect structure 40 are disposed after the formation of the first device layer 14 and the second device layer 28. This process is advantageous because it avoids subjecting the first interconnect structure 30 and the second interconnect structure 40 to high-temperature processes during the formation of the first device layer 14 and the second device layer 28. For example, the processing temperature may be decreased to less than about 600 degrees Celsius. On the other hand, the first device layer 14 and the second device layer 28 may be processed at higher temperatures without compromising the low process temperature of the first interconnect structure 30 and the second interconnect structure 40. By doing so, the reliability of the semiconductor device 100 is increased, as the first device layer 14 and the second device layer 28 are not compromised by excessive heat.

This configuration offers additional advantages in terms of electrical performance. By placing the first device layer 14 and the second device layer 28 between the first interconnect structure 30 and the second interconnect structure 40, the electrical connection path is shortened, reducing the resistance of the device. This, in turn, leads to faster and more efficient signal transmission, lower power consumption, and improved overall system performance. These advantages are beneficial for high-speed and high-frequency applications, such as in communications, computing, and other fields where rapid data processing and low latency are critical.

In some embodiments, the first material layer 18 has a thickness T, the dielectric bonding layer 24 has a thickness T2, and the second material layer 26 has a thickness T3. In some embodiments, the thickness T1 is between about 30 μm and about 100 μm. In some embodiments, the thickness T2 is between about 30 μm and about 100 μm. In some embodiments, the thickness T2 is between about 30 μm and about 100 μm. In some embodiments, the thickness T1, the thickness T2, and the thickness T3 are substantially identical, but the present disclosure is not limited thereto. If the thickness is too small, it is not easy to control the thickness. If the thickness is too large, the opening for forming the vias 48 should be deeper, and the pitch of the vias may be increased, which is disadvantageous for the process and the performance of the final product.

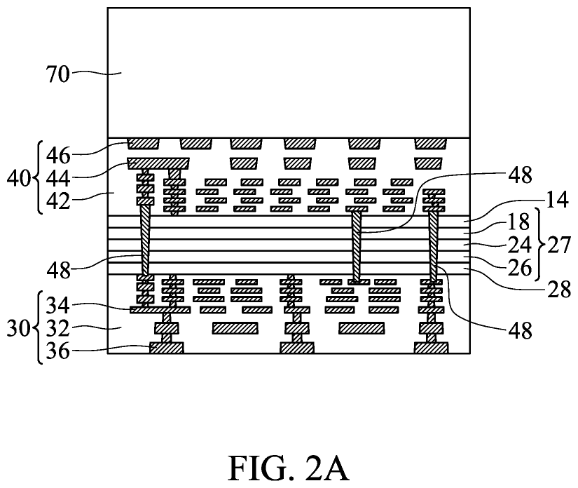

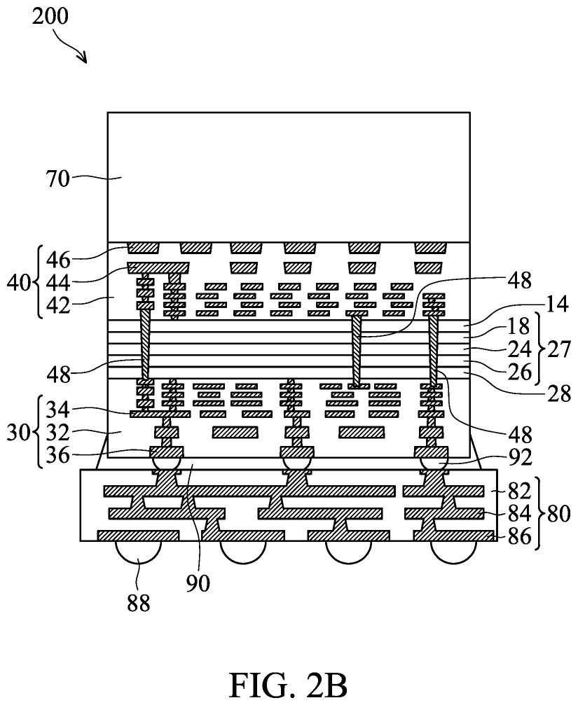

In some embodiments, another bonding and debonding process is performed to allow an interposer be disposed on the second interconnect structure 40. FIGS. 2A and 2B show processes for forming a semiconductor device 200 with an interposer 80 disposed on the second interconnect structure 40, in accordance with some embodiments. The step shown in FIG. 2A is followed after the step shown in FIG. 1H, and same process is not described again for simplicity.

As shown in FIG. 2A, a third substrate 70 is bonded to the second interconnect structure 40, and then the second substrate 38 is de-bonded from the first interconnect structure 30 to expose the conductive pads 36.

In some embodiments, the third substrate 70 may be a semiconductor wafer such as a silicon wafer. Alternatively or additionally, the third substrate 70 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, as shown in FIG. 2B, an interposer 80 is disposed below the first interconnect structure 30 through electrical connectors 92. In some embodiments, the width of the vias 48 gradually decreases from the third substrate 70 to the interposer 80.

In some embodiments, the interposer 80 includes a board 82 and conductive elements 84 and conductive pads 86 disposed in the board 82. In some embodiments, the board 82 may be made of or include a polymer material, a ceramic material, a metal material, a semiconductor material, one or more other suitable materials, or a combination thereof. For example, the board 82 includes resin, prepreg, glass, and/or ceramic. In cases where the board 82 is made of a metal material or a semiconductor material, dielectric layers may be formed between the board 82 and the conductive elements 84 and conductive pads 86 to prevent short circuiting. The conductive elements 84 and the conductive pads 86 may include conductive wires and vias, and may be made of or include copper, aluminum, cobalt, nickel, gold, silver, tungsten, one or more other suitable materials, or a combination thereof.

In some embodiments, electrical connectors 88 may be disposed on the interposer 80 and in contact with the conductive pads 86 to perform electrical connection. In some embodiments, the electrical connectors 92 may include conductive pillars, solder balls, controlled collapse chip connection (C4) bumps, micro bumps, one or more other suitable bonding structures, or a combination thereof.

In some embodiments, an underfill layer 90 is provided between the first interconnect structure 30 and the interposer 80 and surrounding the electrical connectors 92 to protect the electrical connectors 92. In some embodiments, the underfill layer 90 may include an epoxy, a resin, a filler material, a stress release agent (SRA), an adhesion promoter, another suitable material, or a combination thereof. In some embodiments, the fillers may include insulating fibers, insulating particles, other suitable elements, or a combination thereof. In some embodiments, an underfill material in liquid state is dispensed into a gap between first interconnect structure 30 and the interposer 80 to reinforce the strength of the electrical connectors 92 and therefore the overall package structure. After the dispensing, the underfill material is cured to form the underfill layer 90. In some other embodiments, the underfill layer 90 is not formed.

In some embodiments, the electrical connectors 92 may include conductive pillars, solder balls, controlled collapse chip connection (C4) bumps, micro bumps, one or more other suitable bonding structures, or a combination thereof. Therefore, the formation of the semiconductor device 200 is completed.

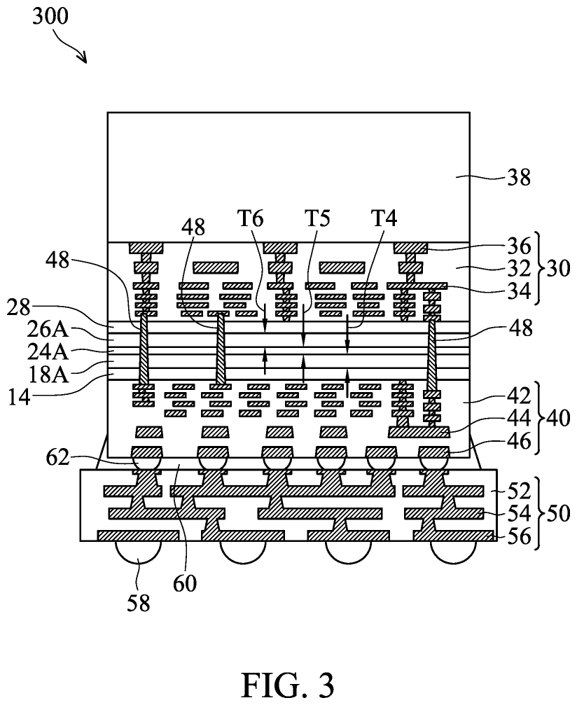

FIG. 3 is a schematic view of a semiconductor device 300, in accordance with some embodiments of the present disclosure. The semiconductor device 300 is similar to the semiconductor device 100, and the difference is that the semiconductor device 300 has a first material layer 18A with a thickness T4, a dielectric bonding layer 24A with a thickness T5, and the second material layer 26A with a thickness T6. In some embodiments, the thickness T5 may be less than the thickness T4 and the thickness T6, which reduces the overall thickness of the semiconductor device 300 to achieve miniaturization. In some embodiments, the thickness T4 and the thickness T6 may be substantially identical.

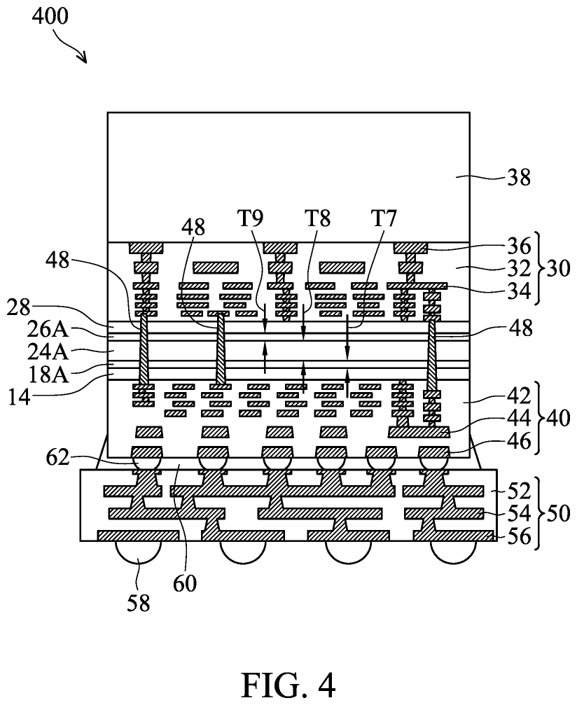

FIG. 4 is a schematic view of a semiconductor device 400, in accordance with some embodiments of the present disclosure. The semiconductor device 400 is similar to the semiconductor device 100, and the difference is that the semiconductor device 400 has a first material layer 18B with a thickness T7, a dielectric bonding layer 24B with a thickness T8, and the second material layer 26B with a thickness T9. In some embodiments, the thickness T7 and the thickness T9 may be less than the thickness T8, which reduces the overall thickness of the semiconductor device 400 to achieve miniaturization. In some embodiments, the thickness T9 and the thickness T7 may be substantially identical.

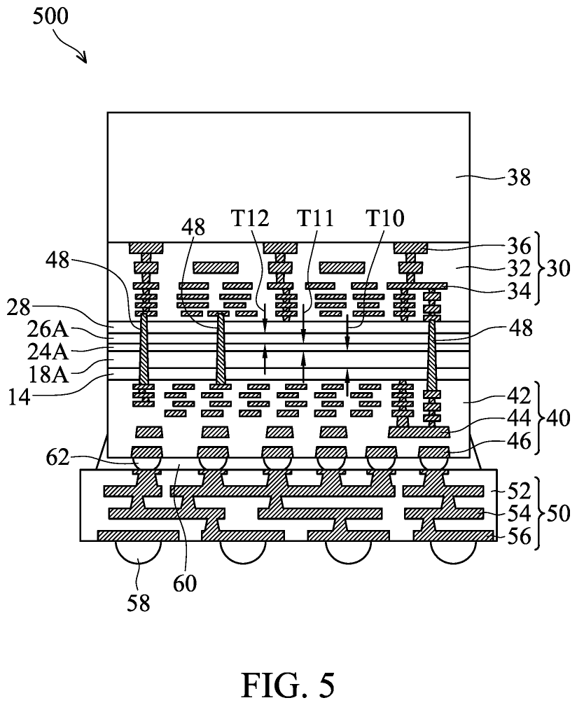

FIG. 5 is a schematic view of a semiconductor device 500, in accordance with some embodiments of the present disclosure. The semiconductor device 500 is similar to the semiconductor device 100, and the difference is that the semiconductor device 500 has a first material layer 18C with a thickness T10, a dielectric bonding layer 24C with a thickness T11, and the second material layer 26C with a thickness T12. In some embodiments, the thickness T12 may be less than the thickness T11, and the thickness T11 may be less than the thickness T10.

In summary, A back-to-back monolithic 3D stacking process and semiconductor devices made by this process are proposed in some embodiments of the present disclosure. The process allows the interconnect structures formed after the formation of the device layers, which not only prevents interconnect structures suffering from high process temperature of the device layers, but also enhances the performance of the semiconductor device.

A method for forming a semiconductor device is provided in some embodiments of the present disclosure. The method includes forming a first device layer on a first substrate. The method further includes forming a dielectric structure on the first device layer. The method further includes forming a second device layer on the dielectric structure, wherein the first device layer and the second device layer are disposed on opposite sides of the dielectric structure. After the second device layer is formed on the dielectric structure, the method further includes forming a first interconnect structure on the second device layer. The method further includes removing the first substrate to expose the first device layer. The method further includes forming vias through the dielectric structure. After the vias are formed, the method further includes forming a second interconnect structure on the first device layer, wherein the vias are electrically connected to both the first interconnect structure and the second interconnect structure.

A method for forming a semiconductor device is provided in some embodiments of the present disclosure. The method includes forming a first device layer over a first material layer. The method further includes bonding a second material layer to the first material layer through a dielectric bonding layer. The method further includes forming a second device layer over the second material layer. The method further includes forming a first interconnect structure over the second device layer. The method further includes forming a via passing through the first material layer, the dielectric bonding layer, and the second material layer. The method further includes forming a second interconnect structure below the first device layer.

A semiconductor device is provided in some embodiments of the present disclosure. The semiconductor device includes a first interconnect structure, a first device layer disposed on the first interconnect structure, a dielectric structure disposed on the first device layer, a second device layer disposed on the dielectric structure, and a second interconnect structure disposed on the second device layer. In some embodiments, a first side of the first interconnect structure faces a second side of the first device layer and a second side of the second device layer, and a first side of the second interconnect structure faces a first side of the first device layer and a first side of the second device layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device, comprising:
forming a first device layer on a first substrate;
forming a dielectric structure on the first device layer;
forming a second device layer on the dielectric structure, wherein the first device layer and the second device layer are disposed on opposite sides of the dielectric structure;
after the second device layer is formed on the dielectric structure, forming a first interconnect structure on the second device layer;
removing the first substrate to expose the first device layer;
forming vias through the dielectric structure; and
after the vias are formed, forming a second interconnect structure on the first device layer, wherein the vias are electrically connected to both the first interconnect structure and the second interconnect structure.

2. The method for forming the semiconductor device as claimed in claim 1,
wherein forming the dielectric structure comprises:
forming a first material layer on the first device layer; and
bonding a second material layer to the first material layer through a dielectric bonding layer.

3. The method for forming the semiconductor device as claimed in claim 2, wherein forming the first material layer comprises forming a first etch stop layer in a first wafer; and
thinning the first wafer until the first etch stop layer is removed to form the first material layer.

4. The method for forming the semiconductor device as claimed in claim 2, wherein forming the second material layer comprises forming a second etch stop layer in a second wafer; and
thinning the second wafer until the second etch stop layer is removed to form the second material layer.

5. The method for forming the semiconductor device as claimed in claim 1, further comprising forming an interposer on the first interconnect structure.

6. The method for forming the semiconductor device as claimed in claim 1, further comprising forming an interposer on the second interconnect structure.

7. The method for forming the semiconductor device as claimed in claim 1, wherein the vias extend from the first interconnect structure to the second interconnect structure through the first device layer and the second device layer.

8. The method for forming the semiconductor device as claimed in claim 1, wherein the first device layer and the second device layer are between the first interconnect structure and the second interconnect structure.

9. The method for forming the semiconductor device as claimed in claim 1, wherein the dielectric structure is in direct contact with the first device layer and the second device layer.

10. A method for forming a semiconductor device, comprising:
forming a first device layer over a first material layer;
bonding a second material layer to the first material layer through a dielectric bonding layer;
forming a second device layer over the second material layer;
forming a first interconnect structure over the second device layer;
forming a via passing through the first material layer, the dielectric bonding layer, and the second material layer; and
forming a second interconnect structure below the first device layer.

11. The method for forming the semiconductor device as claimed in claim 10, wherein the first interconnect structure is separated from the second material layer by the second device layer, and the second interconnect structure is separated from the first material layer by the first device layer.

12. The method for forming the semiconductor device as claimed in claim 10, wherein the via passes through the first device layer and the second device layer.

13. The method for forming the semiconductor device as claimed in claim 10, further comprising forming an interposer over the first interconnect structure.

14. The method for forming the semiconductor device as claimed in claim 10, further comprising forming an interposer below the second interconnect structure.

15. A semiconductor device, comprising:
a first interconnect structure;
a first device layer disposed on the first interconnect structure;
a dielectric structure disposed on the first device layer;
a second device layer disposed on the dielectric structure; and
a second interconnect structure disposed on the second device layer;
wherein a first side of the first interconnect structure faces a second side of the first device layer and a second side of the second device layer, and a first side of the second interconnect structure faces a first side of the first device layer and a first side of the second device layer.

16. The semiconductor structure as claimed in claim 15, wherein the dielectric structure comprises a first material layer, a second material layer, and a dielectric bonding layer disposed between the first material layer and the second material layer.

17. The semiconductor structure as claimed in claim 15, wherein the first material layer and the dielectric bonding layer are different in thickness.

18. The semiconductor structure as claimed in claim 15, wherein the first material layer and the second material layer are different in thickness.

19. The semiconductor structure as claimed in claim 15, further comprising a substrate in contact with a second side of the first interconnect structure.

20. The semiconductor structure as claimed in claim 19, further comprising:
a via penetrating the first device layer, the dielectric structure, and the second device layer; and
an interposer disposed on the second interconnect structure, wherein a width of the via gradually increases from the substrate to the interposer.
